(19) United States
(12) Patent Application Publication
(10) Pub. No.: US 2022/0319991 A1
(43) Pub. Date: Oct. 6, 2022

(54) SEMICONDUCTOR DEVICE WITH DUAL BARRIER LAYERS AND METHOD FOR FABRICATING THE SAME

(71) Applicant: NANYA TECHNOLOGY CORPORATION, New Taipei City (TW)

(72) Inventor: Liang-Pin CHOU, TAOYUAN CITY (TW)

(21) Appl. No.: 17/218,990

(22) Filed: Mar. 31, 2021

(51) Int. Cl. H01L 23/528; H01L 21/768; H01L 21/285; H01L 23/522

(52) U.S. Cl. CPC H01L 23/5283; H01L 21/76802; H01L 21/76843; H01L 21/28506; H01L 21/7684; H01L 23/5226

(57) ABSTRACT

The present application discloses a semiconductor device and a method for fabricating the semiconductor device. The semiconductor device includes a target layer, a hole inwardly positioned from a top surface of the target layer and including a bottom surface and two sidewalls adjoining to two ends of the bottom surface, a first barrier layer conformally positioned on the bottom surface of the hole and the two sidewalls of the hole, a second barrier layer conformally positioned on the first barrier layer, and a top conductive layer positioned on the second barrier layer. A thickness of the first barrier layer positioned on the bottom surface of the hole is greater than a thickness of the first barrier layer positioned on the two sidewalls of the hole. The second barrier has a substantially uniform thickness.

### TECHNICAL FIELD

The present disclosure relates to a semiconductor device and a method for fabricating the semiconductor device, and more particularly, to a semiconductor device with dual barrier layers and a method for fabricating the semiconductor device the dual barrier layers.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a target layer, a hole inwardly positioned from a top surface of the target layer and including a bottom surface and two sidewalls adjoining to two ends of the bottom surface, a first barrier layer conformally positioned on the bottom surface of the hole and the two sidewalls of the hole, a second barrier layer conformally positioned on the first barrier layer, and a top conductive layer positioned on the second barrier layer. A thickness of the first barrier layer positioned on the bottom surface of the hole is greater than a thickness of the first barrier layer positioned on the two sidewalls of the hole. The second barrier has a substantially uniform thickness.

In some embodiments, the two sidewalls of the hole are curved and faced to each other.

In some embodiments, the two sidewalls have uniform slopes.

In some embodiments, the target layer includes a bottom layer, a first dielectric layer positioned on the bottom layer, and a second dielectric layer positioned on the first dielectric layer. The hole is positioned along the first dielectric layer and the second dielectric layer. The bottom surface of the hole is substantially coplanar with a top surface of the bottom layer.

In some embodiments, an aspect ratio of the hole is between about 1:1 and about 1:25.

In some embodiments, the first barrier comprises titanium, titanium nitride, titanium silicide, or a combination thereof.

In some embodiments, the second barrier layer comprises titanium nitride.

Another aspect of the present disclosure provides a semiconductor device including a target layer, a hole inwardly positioned from a top surface of the target layer and including a bottom surface and two sidewalls adjoining to two ends of the bottom surface, a first barrier layer including a bottom portion conformally positioned on the bottom surface of the hole and two side portions conformally positioned on the two sidewalls of the hole and connecting to two ends of the bottom portion, a second barrier layer conformally positioned on the first barrier layer, a middle insulation layer conformally positioned on the second barrier layer, and a top conductive layer positioned on the middle insulation layer. A thickness of the bottom portion of the first barrier layer is greater than thicknesses of the two sidewall portions of the first barrier layer. The second barrier has a substantially uniform thickness.

In some embodiments, the two sidewalls of the hole are curved and faced to each other.

In some embodiments, the target layer includes a bottom layer, a first dielectric layer positioned on the bottom layer, and a second dielectric layer positioned on the first dielectric layer. The hole is positioned along the first dielectric layer and the second dielectric layer. The bottom surface of the hole is substantially coplanar with a top surface of the bottom layer.

Another aspect of the present disclosure provides a method for fabricating a semiconductor device including providing a target layer, forming a hole in the target layer, conformally forming a first barrier layer in the hole, conformally forming a second barrier layer on the first barrier layer, and forming a top conductive layer (FIG. 8, 603) on the second barrier layer to fill the hole. The hole includes a bottom surface and two sidewalls adjoining to two ends of the bottom surface. A thickness of the first barrier layer formed on the bottom surface of the hole is greater than a thickness of the first barrier layer formed on the two sidewalls of the hole. The second barrier layer has a substantially uniform thickness.

In some embodiments, the first barrier layer is formed by using a source gas containing a precursor and a reductant through chemical vapor deposition.

In some embodiments, the precursor is titanium tetrachloride and the reductant is hydrogen gas.

In some embodiments, the step of conformally forming the first barrier layer includes introducing a source gas containing a precursor onto the hole to form a continuous thin film on the hole, and flowing a reactant to turn the continuous thin film into the first barrier layer.

In some embodiments, the precursor is titanium tetrachloride and the reactant is ammonia.

In some embodiments, the step of conformally forming the second barrier layer on the first barrier layer includes introducing a source gas containing precursor and a reactant onto the first barrier layer to form a continuous thin film on the first barrier layer, and introducing the reactant to turn the continuous thin film into the second barrier layer.

In some embodiments, the precursor is tetrachloride and the reactant is ammonia.

In some embodiments, the step of conformally forming the second barrier layer on the first barrier layer includes introducing a source gas containing precursor onto the first barrier layer to form a monolayer on the first barrier layer, and introducing a reactant to turn the monolayer into the second barrier layer.

In some embodiments, the precursor is tetrachloride and the reactant is ammonia.

In some embodiments, the first barrier is formed of titanium, titanium nitride, titanium silicide, or a combination thereof.

Due to the design of the semiconductor device of the present disclosure, step coverage for the hole may be improved. As a result, the following filling of the top conductive layer may be proceeded without formation of void. Therefore, reliability of the semiconductor device may be increased.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIGS. 2 and 3 illustrate, in schematic cross-sectional view diagrams, part of a flow for fabricating the semiconductor device in accordance with one embodiment of the present disclosure;

FIG. 4 is a chart showing an example of process conditions for forming a first barrier layer in accordance with one embodiment of the present disclosure;

FIG. 5 illustrates, in a schematic cross-sectional view diagram, part of the flow for fabricating the semiconductor device in accordance with one embodiment of the present disclosure;

FIGS. 6 and 7 are charts showing examples of process conditions for forming a second barrier layer in accordance with some embodiments of the present disclosure;

FIGS. 8 and 9 illustrate, in schematic cross-sectional view diagrams, part of the flow for fabricating the semiconductor device in accordance with one embodiment of the present disclosure;

FIG. 10 illustrates, in a schematic cross-sectional view diagram, a semiconductor device in accordance with another embodiment of the present disclosure;

FIGS. 11 and 12 illustrate, in schematic cross-sectional view diagrams, part of a flow for fabricating a semiconductor device in accordance with another embodiment of the present disclosure;

FIG. 13 is a chart showing an example of process conditions for forming a first barrier layer in accordance with another embodiment of the present disclosure;

FIGS. 14 and 15 illustrate, in schematic cross-sectional view diagrams, part of the flow for fabricating the semiconductor device in accordance with another embodiment of the present disclosure;

FIGS. 16 to 18 illustrate, in schematic cross-sectional view diagrams, semiconductor devices in accordance with some embodiments of the present disclosure;

FIGS. 19 to 22 illustrate, in schematic cross-sectional view diagrams, a flow for fabricating a semiconductor device in accordance with another embodiment of the present disclosure;

FIGS. 23 and 24 illustrate, in schematic cross-sectional view diagrams, a flow for fabricating a semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

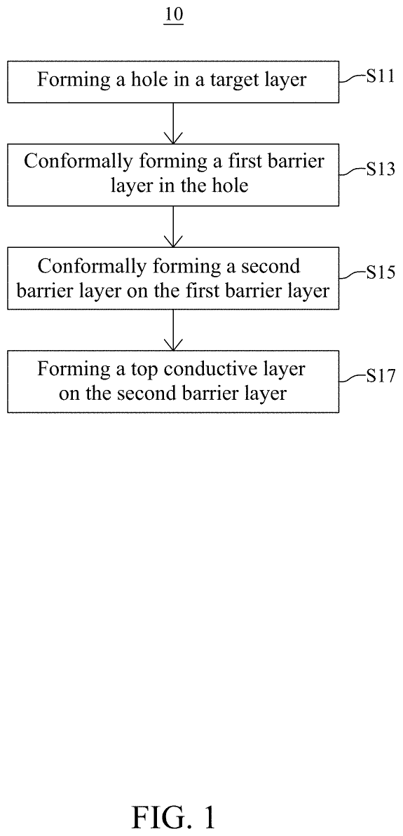

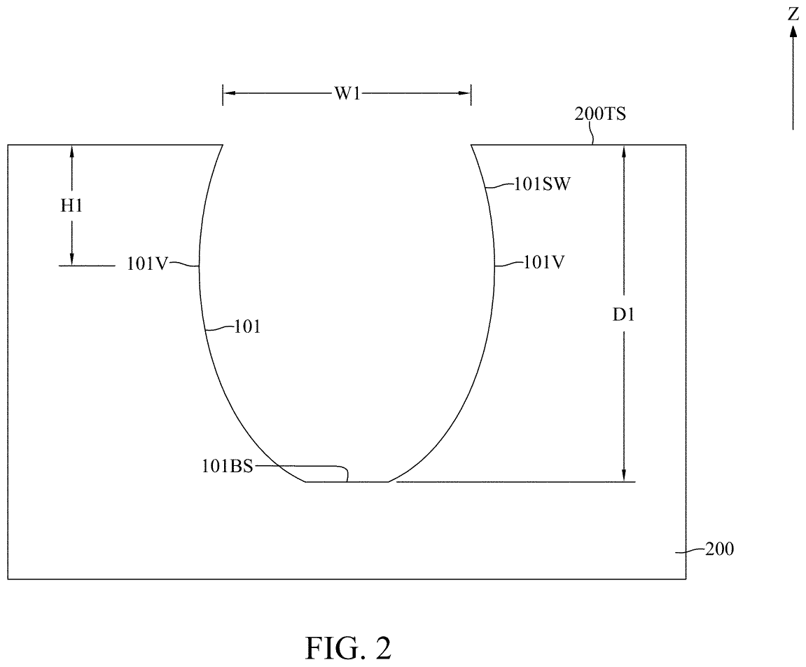

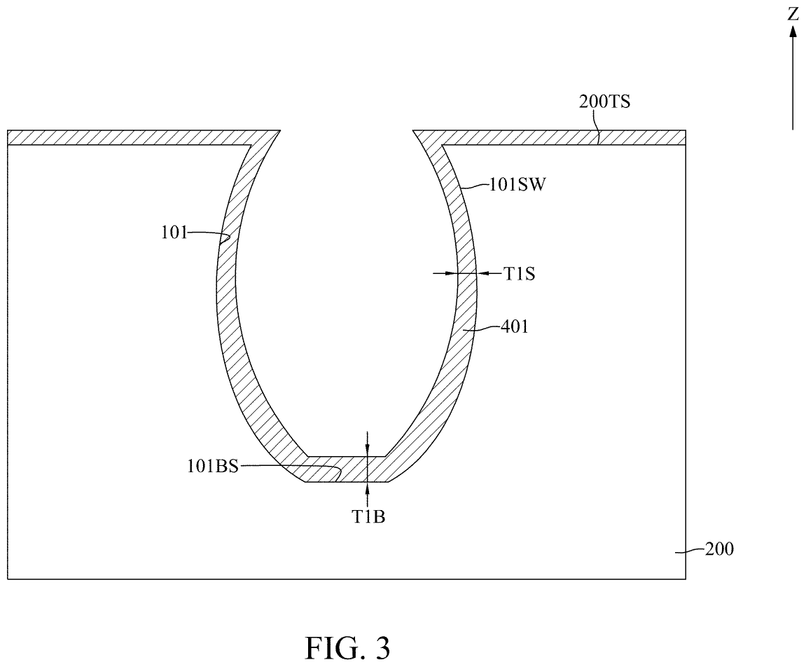

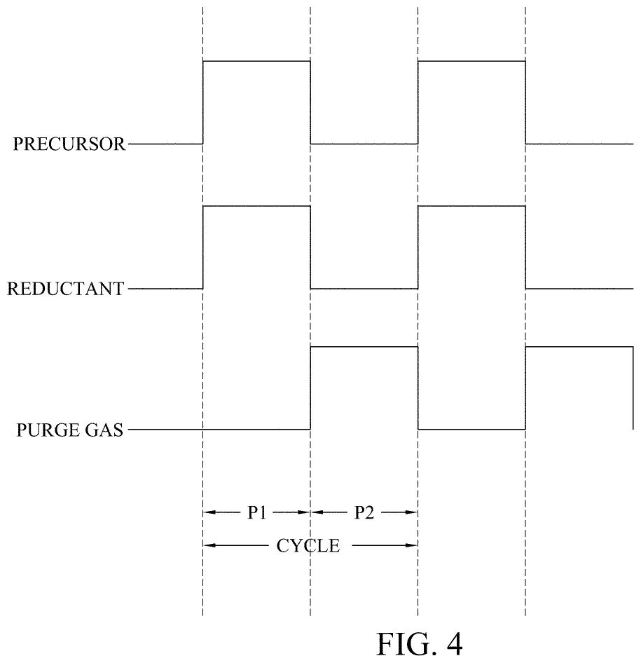

FIG. 1 illustrates, in a flowchart diagram form, a method 10 for fabricating a semiconductor device 1A in accordance with one embodiment of the present disclosure. FIGS. 2 and 3 illustrate, in schematic cross-sectional view diagrams, part of a flow for fabricating the semiconductor device 1A in accordance with one embodiment of the present disclosure. FIG. 4 is a chart showing an example of process conditions for forming a first barrier layer in accordance with one embodiment of the present disclosure.

With reference to FIGS. 1 and 2, at step S11, a hole 101 may be formed in a target layer 200. In some embodiments, the target layer 200 may include bulk silicon, or another suitable semiconductor material. In some embodiments, the target layer 200 may include a silicon-containing material. Illustrative examples of silicon-containing materials suitable for the target layer 200 may include, but are not limited to, silicon, silicon germanium, carbon doped silicon germanium, silicon germanium carbide, carbon-doped silicon, silicon carbide, and multi-layers thereof. In the present embodiment, the target layer 200 may be formed of silicon and may be referred to as a substrate.

In some embodiments, the target layer 200 may be doped with impurities. Doped target layer 200 may have a conductivity type such as p-type or n-type. The “p-type” refers to the addition of impurities to an intrinsic semiconductor that creates deficiencies of valence electrons. In a silicon-containing material, examples of p-type dopants, i.e., impurities include but are not limited to: boron, aluminum, gallium and indium. The “n-type” refers to the addition of impurities that contribute free electrons to an intrinsic semiconductor. In a silicon-containing material, examples of n-type dopants, i.e., impurities, include but are not limited to antimony, arsenic and phosphorus.

In some embodiments, the target layer 200 may include device elements (not shown) formed in a lower portion of the target layer 200. The device elements may be, for example, bipolar junction transistors, metal-oxide-semiconductor field effect transistors, diodes, system large-scale integration, flash memories, dynamic random-access memories, static random-access memories, electrically erasable programmable read-only memories, image sensors, micro-electro-mechanical system, active devices, or passive devices.

With reference to FIG. 2, the hole 101 may be formed in the target layer 200. The hole 101 may be inwardly recessed from a top surface 200TS of the target layer 200. In some embodiments, the hole 101 may be formed by laser drilling, powder blast micromachining, one or more etching processes, for example, deep reactive ion etching, or wet etching using hydroxides such as potassium hydroxide, sodium hydroxide, rubidium hydroxide, ammonium hydroxide, or tetramethyl ammonium hydroxide.

The hole 101 may include a bottom surface 101BS and two sidewalls 101SW. The bottom surface 101BS may be horizontally disposed in a cross-sectional perspective. The two sidewalls 101SW may be connected to two ends of the bottom surface 101BS. In some embodiments, the bottom surface 101BS may be flat. In some embodiments, the bottom surface 101BS may be rounded. Rounded bottom surface 101BS may reduce defect density and reduce electric field concentration during the operating of the semiconductor device 1A.

In some embodiments, the width W1 of the opening of the hole 101 may be between about 1 μm and about 22 μm or between about 5 μm and about 15 μm. In some embodiments, the depth D1 of the hole 101 may be between about 20 μm and about 160 μm or between about 50 μm and about 130 μm. In some embodiments, the width-to-depth aspect ratio of the hole 101 may be between about 1:1 and about 1:25, between about 1:2 and about 1:15, or between about 1:3 and about 1:10.

In some embodiments, the two sidewalls 101SW may be curved in a cross-sectional perspective. In other words, the slopes of the two sidewalls 101SW may not be uniform. Specifically, the two sidewalls 101SW may be a rightward concave and a leftward concave and may be faced to each other. In some embodiments, a ratio between a vertical distance H1 between the valleys 101V of the two sidewalls 101SW and the top surface 200TS of the target layer 200 to the depth D1 of the hole 101 may be between about 1:10 and about 7:10. In some embodiments, the hole 101 may be referred to as a bowing hole. The bowing hole may be formed originating from over etching and distortion of the orbits of ions during the etching process.

With reference to FIGS. 1, 3, and 4, at step S13, a first barrier layer 401 may be conformally formed in the hole 101.

With reference to FIGS. 3 and 4, the first barrier layer 401 may be conformally formed in the hole 101 and on the top surface 200TS of the target layer 200. The thickness T1B of the first barrier layer 401 formed on the bottom surface 101BS of the hole 101 may be greater than the thickness T1S of the first barrier layer 401 formed on the two sidewalls 101SW of the hole 101.

In some embodiments, the first barrier layer 401 may be formed of, for example, a metal silicide such as titanium silicide, nickel silicide, nickel platinum silicide, tantalum silicide, or cobalt silicide. In the present embodiment, the first barrier layer 401 is formed of titanium silicide.

In some embodiments, the first barrier layer 401 may be formed by a deposition process such as chemical vapor deposition, atomic layer deposition, or the like. In the present embodiment, the first barrier layer 401 is formed by chemical vapor deposition. Specifically, with reference to FIG. 4, the formation of the first barrier layer 401 may include a source gas introducing step and a subsequent purging step. The source gas introducing step and the purging step may be referred to as one cycle. Multiple cycles may be performed to obtain the desired thickness of the first barrier layer 401.

The intermediate semiconductor device illustrated in FIG. 2 may be loaded in a reaction chamber and may be pre-heated to a determined temperature. In the source gas introducing step, during a period P1, source gases containing a precursor and a reductant may be introduced to the reaction chamber. It should be noted that the precursor and the reductant may be injected using different inlet valves but are not limited thereto. The precursor may diffuse across the boundary layer and reach the surface of the intermediate semiconductor device illustrated in FIG. 2 (i.e., the top surface 200TS of the target layer 200 and the bottom surface 101BS and two sidewalls 101SW of the hole 101). The precursor may adsorb on and subsequently migrate on the surface aforementioned. The adsorbed precursor may react with the reductant on the surface aforementioned and form solid byproducts and gaseous byproducts. The solid byproducts may form nuclei on the surface aforementioned. The nuclei may grow into islands and the islands may merge into a continuous thin film on the surface aforementioned. In the purging step, during a period P2, a purge gas such as argon may be injected into the reaction chamber to purge out the gaseous byproducts, unreacted precursor, and unreacted reductant. A silicidation of the continuous thin film may be occurred when a process temperature is above 550° C. or a thermal treatment is performed. After the silicidation, the continuous thin film may be turned into the first barrier layer 401. In some embodiments, the thermal treatment may be a dynamic surface annealing process.

For example, the target layer 200 may include silicon. The precursor may be titanium tetrachloride. The reductant may be hydrogen gas. Titanium tetrachloride and the hydrogen gas may react on the surface and form a titanium film and gaseous hydrogen chloride. The metal atoms (i.e., titanium atoms) of the titanium film may react chemically with silicon atoms of target layer 200 to form the first barrier layer 401 formed of titanium silicide. A cleaning process may be performed to remove the unreacted titanium film. The cleaning process may use etchant such as hydrogen peroxide and a SC-1 solution.

In some embodiments, the process temperature may be set to above 550° C. during the cycles such that the silicidation may be proceeded immediately after the continuous thin film is formed. In some embodiments, the thermal treatment may be performed after the continuous thin film is completely formed.

In some embodiments, the formation of the first barrier layer 401 using chemical vapor deposition may be performed with assistance of plasma. The source of the plasma may be, for example, argon, hydrogen, or a combination thereof.

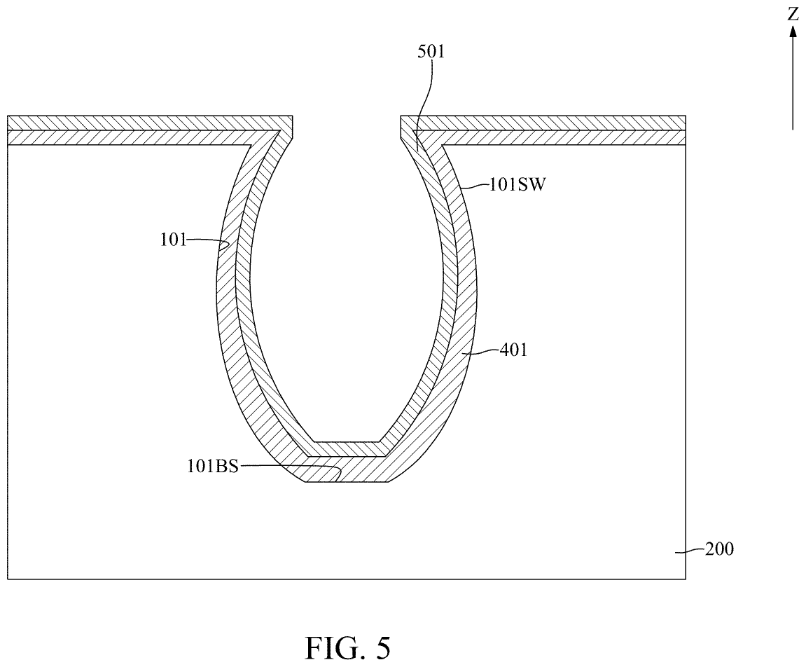

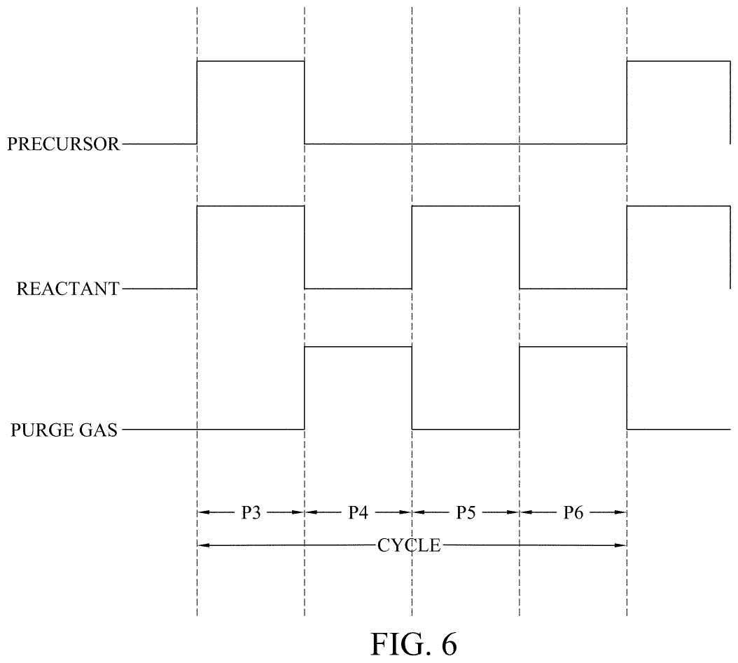

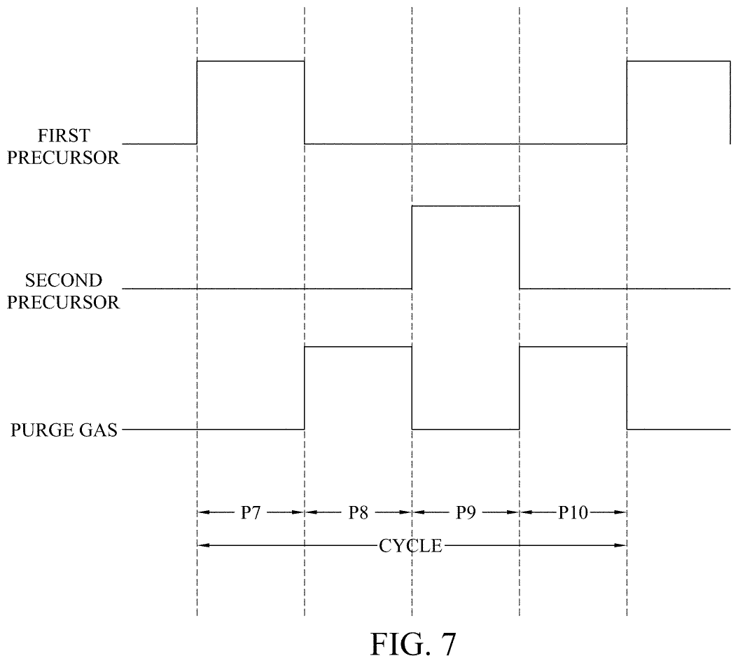

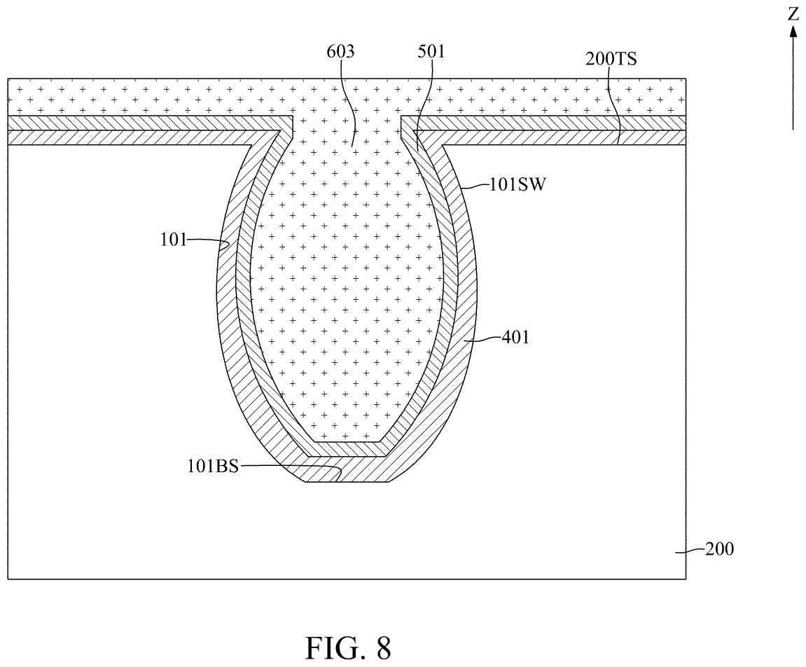

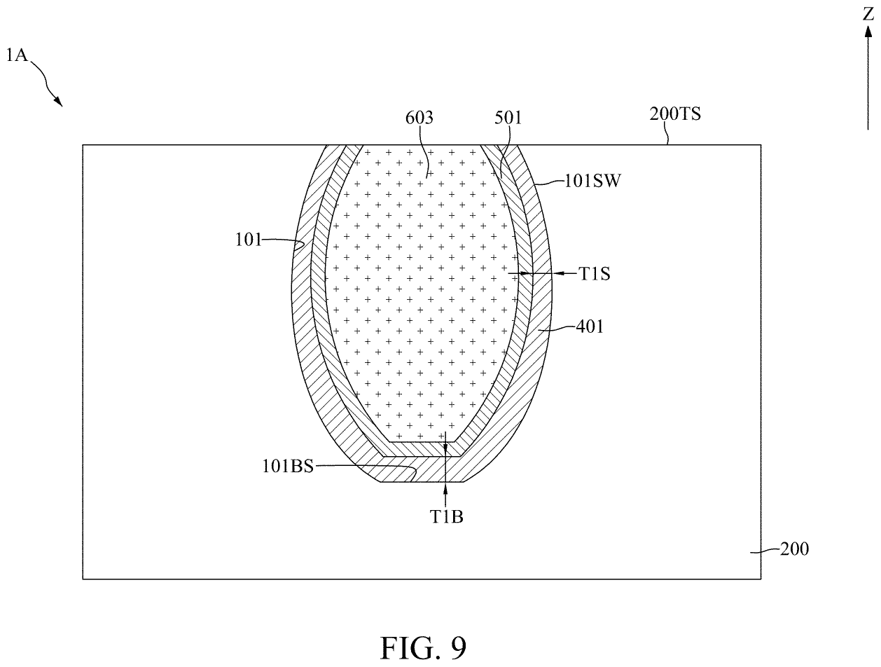

FIG. 5 illustrates, in a schematic cross-sectional view diagram, part of the flow for fabricating the semiconductor device 1A in accordance with one embodiment of the present disclosure. FIGS. 6 and 7 are charts showing examples of process conditions for forming a second barrier layer in accordance with some embodiments of the present disclosure. FIGS. 8 and 9 illustrate, in schematic cross-sectional view diagrams, part of the flow for fabricating the semiconductor device 1A in accordance with one embodiment of the present disclosure.

With reference to FIG. 1 and FIGS. 5 to 7, at step S15, a second barrier layer 501 may be conformally formed on the first barrier layer 401.

With reference to FIG. 5, the second barrier layer 501 may be conformally formed on the first barrier layer 401. It should be noted that the hole 101 is not completely filled by the second barrier layer 501. The second barrier layer 501 may have a substantially uniform thickness. Specifically, the thickness of the second barrier layer 501 formed adjacent to the bottom surface 101BS of the hole 101 and the thickness of the second barrier layer 501 formed adjacent to the sidewalls 101SW of the hole 101 may be substantially the same. In some embodiments, the second barrier layer 501 may be formed of, for example, metal nitride such as titanium nitride or tantalum nitride. In the present embodiment, the second barrier layer 501 is formed of titanium nitride.

With reference to FIG. 6, in some embodiments, the second barrier layer 501 may be formed by chemical vapor deposition. Specifically, the formation of the second barrier layer 501 may include a source gas introducing step, a first purging step, a reactant flowing step, and a second purging step. The source gas introducing step, the first purging step, the reactant flowing step, and the second purging step may be referred to as one cycle. Multiple cycles may be performed to obtain the desired thickness of the second barrier layer 501.

Specifically, the intermediate semiconductor device illustrated in FIG. 3 may be loaded in a reaction chamber. In the source gas introducing step, during a period P3, source gases containing a precursor and a reactant may be introduced to the reaction chamber. The precursor and the reactant may diffuse across the boundary layer and reach the surface of the intermediate semiconductor device illustrated in FIG. 3 (i.e., the surface of the first barrier layer 401). The precursor and the reactant may adsorb on and subsequently migrate on the surface aforementioned. The adsorbed precursor and the adsorbed reactant may react on the surface aforementioned and form solid byproducts. The solid byproducts may form nuclei on the surface aforementioned. The nuclei may grow into islands and the islands may merge into a continuous thin film on the surface aforementioned. In the first purging step, during a period P4, a purge gas such as argon may be injected into the reaction chamber to purge out the gaseous byproducts, unreacted precursor, and unreacted reactant.

In the reactant flowing step, during a period P5, the reactant may be solely introduced to the reaction chamber to turn the continuous thin film into the second barrier layer 501. In the second purging step, during a period P4, a purge gas such as argon may be injected into the reaction chamber to purge out the gaseous byproducts and unreacted reactant.

In some embodiments, the formation of the second barrier layer 501 using chemical vapor deposition may be performed with assistance of plasma. The source of the plasma may be, for example, argon, hydrogen, or a combination thereof.

For example, the precursor may be titanium tetrachloride. The reactant may be ammonia. Titanium tetrachloride and ammonia may react on the surface and form a titanium nitride film including high chloride contamination due to incomplete reaction between titanium tetrachloride and ammonia. The ammonia in the reactant flowing step may reduce the chloride content of the titanium nitride film. After the ammonia treatment, the titanium nitride film may be referred to as the second barrier layer 501.

With reference to FIG. 7, in some other embodiments, the second barrier layer 501 may be formed by atomic layer deposition such as photo-assisted atomic layer deposition or liquid injection atomic layer deposition. Specifically, the formation of the second barrier layer 501 may include a first precursor introducing step, a first purging step, a second precursor introducing step, and a second purging step. The first precursor introducing step, the first purging step, the second precursor introducing step, and the second purging step may be referred to as one cycle. Multiple cycles may be performed to obtain the desired thickness of the second barrier layer 501.

Specifically, the intermediate semiconductor device illustrated in FIG. 3 may be loaded in a reaction chamber. In the first precursor introducing step, during a period P7, a first precursor may be introduced to the reaction chamber. The first precursor may diffuse across the boundary layer and reach the surface of the intermediate semiconductor device illustrated in FIG. 3 (i.e., the surface of the first barrier layer 401). The first precursor may adsorb on the surface aforementioned to form a monolayer at a single atomic layer level. In the first purging step, during a period P8, a purge gas such as argon may be injected into the reaction chamber to purge out unreacted first precursor.

In the second precursor introducing step, during a period P9, a second precursor may be introduced to the reaction chamber. The second precursor may react with the monolayer and turn the monolayer into the second barrier layer 501. In the second purging step, during a period P10, a purge gas such as argon may be injected into the reaction chamber to purge out unreacted second precursor and gaseous byproduct. Comparing to the chemical vapor deposition, a particle generation caused by a gas phase reaction may be suppressed because the first precursor and the second are separately introduced.

For example, the first precursor may be titanium tetrachloride. The second precursor may be ammonia. Adsorbed titanium tetrachloride may form a titanium nitride monolayer. The ammonia in the second precursor introducing step may react with the titanium nitride monolayer and turn the titanium nitride monolayer into the second barrier layer 501.

In some embodiments, the formation of the second barrier layer 501 using atomic layer deposition may be performed with assistance of plasma. The source of the plasma may be, for example, argon, hydrogen, oxygen, or a combination thereof. In some embodiments, the oxygen source may be, for example, water, oxygen gas, or ozone. In some embodiments, co-reactants may be introduced to the reaction chamber. The co-reactants may be selected from the group consisting of hydrogen, hydrogen plasma, oxygen, air, water, ammonia, hydrazines, alkylhydrazines, boranes, silanes, ozone and a combination thereof.

In some embodiments, the formation of the second barrier layer 501 may be performed using the following process conditions. The substrate temperature may be between about 160° C. and about 300° C. The evaporator temperature may be about 175° C. The pressure of the reaction chamber may be about 5 mbar. The solvent for the first precursor and the second precursor may be toluene.

With reference to FIGS. 1, 8, and 9, at step S17, a top conductive layer 603 may be formed on the second barrier layer 501.

With reference to FIG. 8, the top conductive layer 603 may be formed on the second barrier layer 501 to complete fill the hole 101. The top conductive layer 603 may be formed of, for example, copper, tungsten, aluminum, silver, titanium, tantalum, cobalt, zirconium, ruthenium, metal carbides (e.g., tantalum carbide, titanium carbide, tantalum magnesium carbide), metal nitrides (e.g., titanium nitride), transition metal aluminides, polycrystalline silicon, doped polycrystalline silicon, polycrystalline germanium, doped polycrystalline germanium, polycrystalline silicon germanium, doped polycrystalline silicon germanium, or a combination thereof. The top conductive layer 603 may be formed by, for example, chemical vapor deposition, physical vapor deposition, sputtering, electroplating, or the like.

With reference to FIG. 9, a planarization process, such as chemical mechanical polishing, may be performed until the top surface 200TS of the target layer 200 is exposed to remove excess material, provide a substantially flat surface for subsequent processing steps. The first barrier layer 401 in the hole 101, the second barrier layer 501 in the hole 101, and the top conductive layer 603 in the hole 101 together configure a conductive feature. By employing the first barrier layer 401 and the second barrier layer 501 with different thickness composition, the step coverage for the hole 101 may be improved. As a result, the following filling of the top conductive layer 603 may be proceeded without formation of void. Therefore, reliability of the semiconductor device 1A may be increased.

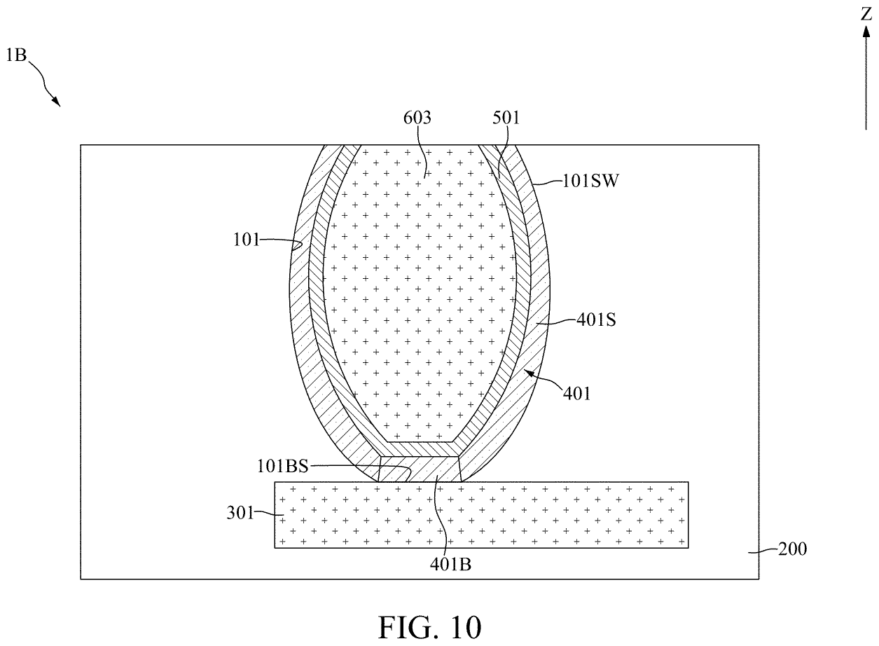

FIG. 10 illustrates, in a schematic cross-sectional view diagram, a semiconductor device 1B in accordance with another embodiment of the present disclosure.

With reference to FIG. 10, the semiconductor device 1B may have a structure similar to that illustrated in FIG. 9. The same or similar elements in FIG. 10 as in FIG. 9 have been marked with similar reference numbers and duplicative descriptions have been omitted.

The semiconductor device 1B may include a first conductive layer 301. The first conductive layer 301 may be disposed below the first barrier layer 401 and contacting the first barrier layer 401. The first conductive layer 301 may be formed of, for example, copper, tungsten, aluminum, silver, titanium, tantalum, cobalt, zirconium, ruthenium, or combinations thereof. In some embodiments, the first conductive layer 301 may be referred to as a pad layer or a conductive line at the back-end-of-line.

The first barrier layer 401 may include a bottom portion 401B and two side portions 401S. The bottom portion 401B may be disposed on the first conductive layer 301. The side portions 401S may be connected to two ends of the bottom portion 401B and disposed on the sidewalls 101SW of the hole 101. In other words, the side portions 401S may contact the target layer 200. The first barrier layer 401 may be formed by a procedure similar to that illustrated in FIGS. 3 and 4. The continuous thin film formed on the first conductive layer 301 may not react with silicon atoms of the target layer 200. Therefore, the resultant bottom portion 401B may be formed of titanium. In contrast, the continuous thin film formed on the sidewalls 101SW of the hole 101 may react with silicon atoms of the target layer 200. As a result, the resultant side portions 401S may be formed of titanium silicide.

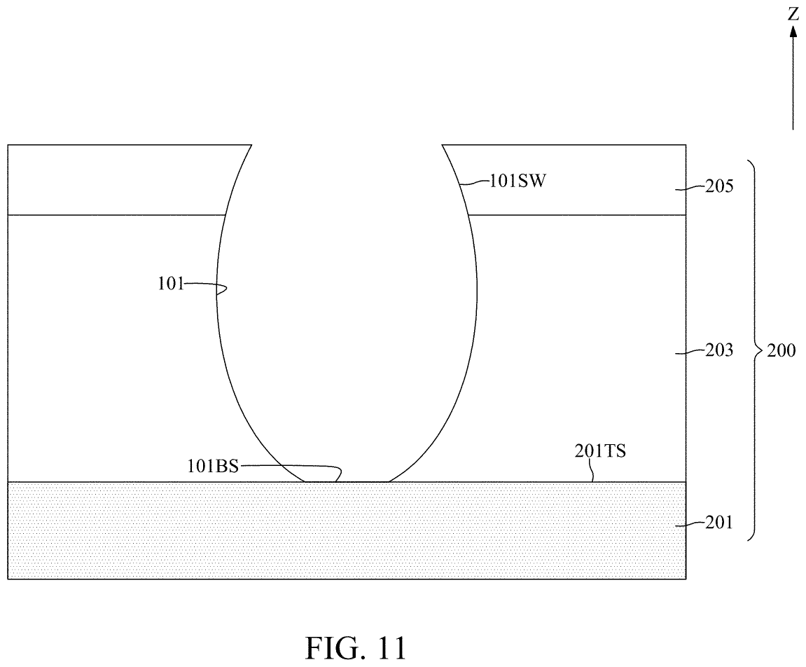

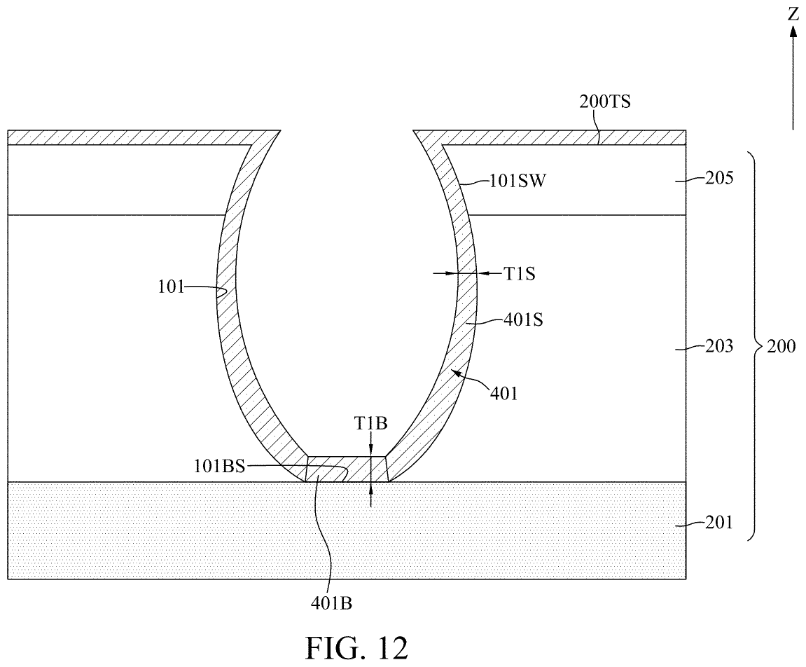

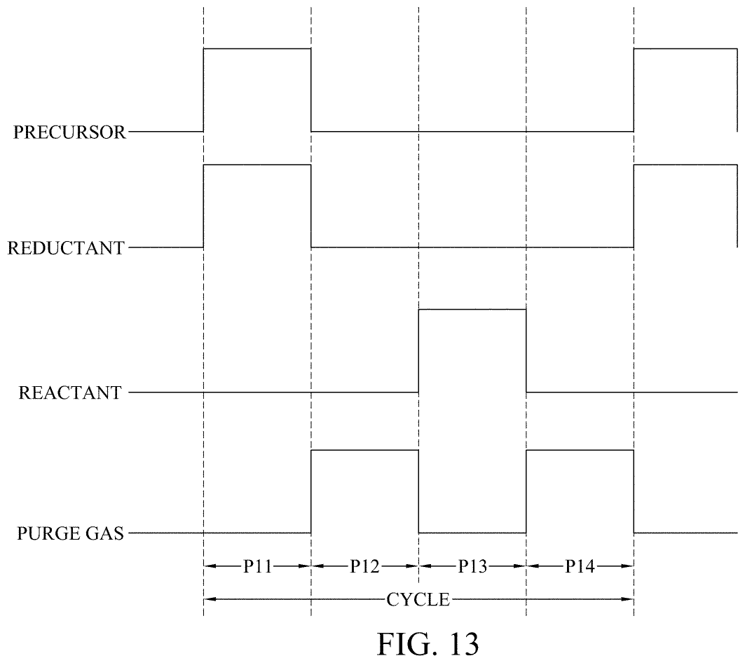

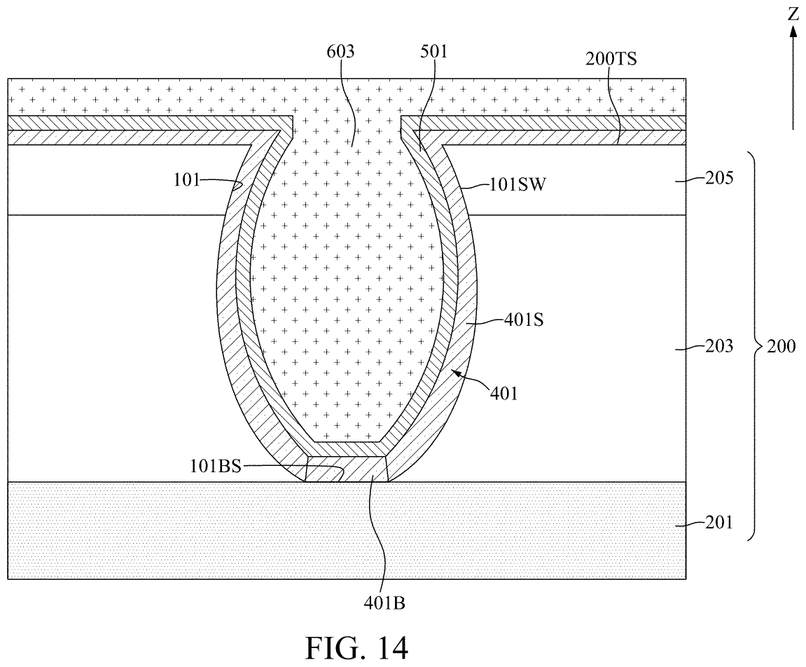

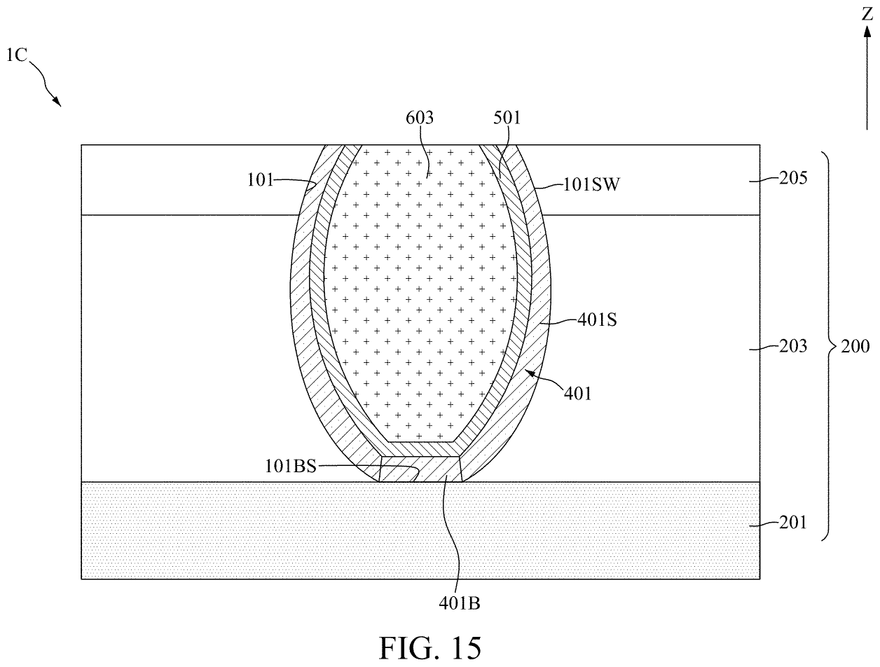

FIGS. 11 and 12 illustrate, in schematic cross-sectional view diagrams, part of a flow for fabricating a semiconductor device 1C in accordance with another embodiment of the present disclosure. FIG. 13 is a chart showing an example of process conditions for forming a first barrier layer in accordance with another embodiment of the present disclosure. FIGS. 14 and 15 illustrate, in schematic cross-sectional view diagrams, part of the flow for fabricating the semiconductor device 1C in accordance with another embodiment of the present disclosure.

With reference to FIG. 11, a hole 101 may be formed in a target layer 200. The target layer 200 may include a bottom layer 201, a first dielectric layer 203, and a second dielectric layer 205. The first dielectric layer 203 may be formed on the bottom layer 201. The second dielectric layer 205 may be formed on the first dielectric layer 203. In some embodiments, the bottom layer 201 may be formed of, for example, silicon, germanium, silicon germanium, or the like. In the present embodiment, the bottom layer 201 is formed of silicon. The first dielectric layer 203 and the second dielectric layer 205 may be formed of, for example, silicon nitride, silicon oxide, silicon oxynitride, silicon nitride oxide, flowable oxide, undoped silica glass, borosilica glass, phosphosilica glass, borophosphosilica glass, plasma-enhanced tetraethyl orthosilicate, fluoride silicate glass, carbon-doped silicon oxide, porous polymeric material, or a combination thereof.

With reference to FIG. 11, the hole 101 may be formed along the second dielectric layer 205 and the first dielectric layer 203. The hole 101 may include a bottom surface 101BS and two sidewalls 101SW. The bottom surface 101BS may be substantially coplanar with the top surface 201TS of the bottom layer 201. A portion of the top surface 201TS of the bottom layer 201 may be exposed through the hole 101. The two sidewalls 101SW may be connected to two ends of the bottom surface 101BS. In some embodiments, the two sidewalls 101SW may have curved cross-sectional profile as illustrated in FIG. 2.

With reference to FIG. 12, a first barrier layer 401 may be conformally formed in the hole 101 and on the top surface of the target layer 200. The first barrier layer 401 may include a bottom portion 401B and two side portions 401S. The bottom portion 401B may be formed on the bottom layer 201. The two side portions 401S may be connected to two ends of the bottom portion 401B and disposed on the sidewalls 101SW of the hole 101. The thickness T1B of the bottom portion 401B may be greater than the thickness T1S of the two side portions 401S.

With reference to FIG. 13, in the present embodiment, the first barrier layer 401 is formed by chemical vapor deposition. Specifically, the formation of the first barrier layer 401 may include a source gas introducing step, a first purging step, a reactant flowing step, and a second purging step. The source gas introducing step, the first purging step, the reactant flowing step, and the second purging step may be referred to as one cycle. Multiple cycles may be performed to obtain the desired thickness of the first barrier layer 401.

The intermediate semiconductor device illustrated in FIG. 12 may be loaded in a reaction chamber and may be pre-heated to a determined temperature. In the source gas introducing step, during a period P11, source gases containing a precursor and a reductant may be introduced to the reaction chamber. It should be noted that the precursor and the reductant may be injected using different inlet valves but are not limited thereto. The precursor may diffuse across the boundary layer and reach the surface of the intermediate semiconductor device illustrated in FIG. 12 (i.e., the top surface of the target layer 200 and the bottom surface 101BS and two sidewalls 101SW of the hole 101). The precursor may adsorb on and subsequently migrate on the surface aforementioned. The adsorbed precursor may react with the reductant on the surface aforementioned and form solid byproducts and gaseous byproducts. The solid byproducts may form nuclei on the surface aforementioned. The nuclei may grow into islands and the islands may merge into a continuous thin film on the surface aforementioned. In the first purging step, during a period P12, a purge gas such as argon may be injected into the reaction chamber to purge out the gaseous byproducts, unreacted precursor, and unreacted reductant.

A silicidation of the continuous thin film formed on the bottom layer 201 may be occurred when a process temperature is above 550° C. or a thermal treatment is performed. After the silicidation, the continuous thin film formed on the bottom layer 201 may be turned into the bottom portion 401B of the first barrier layer 401. In some embodiments, the thermal treatment may be a dynamic surface annealing process.

In the reactant flowing step, during a period P13, the reactant may be solely introduced to the reaction chamber to turn the continuous thin film formed on the two sidewalls 101SW into the side portions 401S of the first barrier layer 401. In the second purging step, during a period P14, a purge gas such as argon may be injected into the reaction chamber to purge out the gaseous byproducts and unreacted reactant.

For example, the bottom layer 201 may include silicon. The precursor may be titanium tetrachloride. The reductant may be hydrogen gas. The reactant may be ammonia. In the source gas introducing step, titanium tetrachloride and the hydrogen gas may react on the surface and form a titanium film and gaseous hydrogen chloride. The metal atoms (i.e., titanium atoms) of the titanium film formed on the bottom layer 201 may react chemically with silicon atoms of bottom layer 201 to form the bottom portion 401B of the first barrier layer 401. In other words, the bottom portion 401B of the first barrier layer 401 is formed of titanium silicide. In the reactant flowing step, ammonia may react with the titanium film formed on the two sidewalls 101SW of the hole 101 and turn the titanium film formed on the two sidewalls 101SW into the two side portions 401S formed of titanium nitride.

In some embodiments, the process temperature may be set to above 550° C. during the cycles such that the silicidation may be proceeded immediately after the continuous thin film is formed. In some embodiments, the thermal treatment may be performed after the continuous thin film is completely formed.

In some embodiments, the formation of the first barrier layer 401 using chemical vapor deposition may be performed with assistance of plasma. The source of the plasma may be, for example, argon, hydrogen, or a combination thereof.

With reference to FIGS. 14 and 15, a second barrier layer 501 may be conformally formed on the first barrier layer 401 with a procedure similar to that illustrated in FIGS. 5 to 7. A top conductive layer 603 may be formed with a procedure similar to that illustrated in FIG. 8. A planarization process, such as chemical mechanical polishing, may be subsequently performed until the top surface of the second dielectric layer 205 is exposed to remove excess material and provide a substantially flat surface for subsequent processing steps.

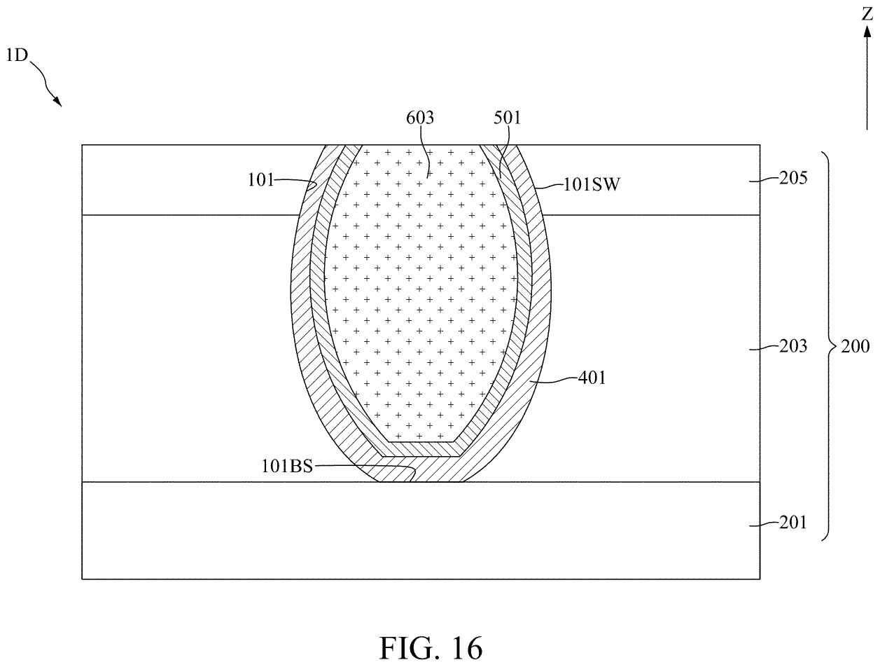

FIGS. 16 to 18 illustrate, in schematic cross-sectional view diagrams, semiconductor devices 1D, 1E, and 1F in accordance with some embodiments of the present disclosure.

With reference to FIG. 16, the semiconductor device 1D may have a structure similar to that illustrated in FIG. 15. The same or similar elements in FIG. 16 as in FIG. 15 have been marked with similar reference numbers and duplicative descriptions have been omitted. The bottom layer 201 of the semiconductor device 1D may be formed of, for example, silicon nitride, silicon oxide, silicon oxynitride, silicon nitride oxide, flowable oxide, undoped silica glass, borosilica glass, phosphosilica glass, borophosphosilica glass, plasma-enhanced tetraethyl orthosilicate, fluoride silicate glass, carbon-doped silicon oxide, porous polymeric material, or a combination thereof. The bottom layer 201 may be referred to as an interlayer dielectric at the middle-end-of-line or back-end-of-line.

Due to the material of the bottom layer 201, no silicon atoms can react with the titanium film to form titanium silicide. As a result, the titanium film formed on the bottom layer 201 may also react with ammonia to be turned into titanium nitride. Therefore, the first barrier layer 401 may be all formed of titanium nitride.

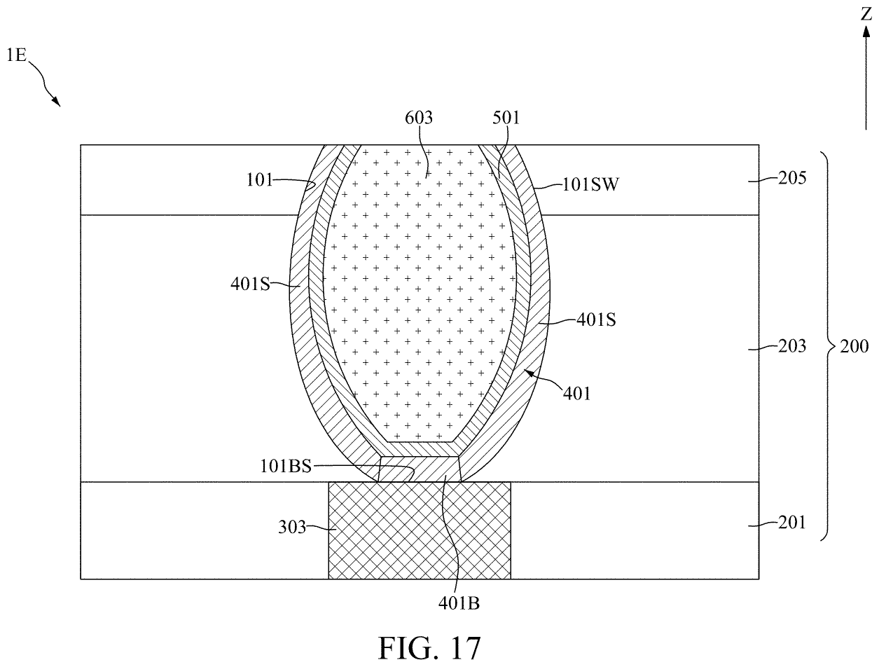

With reference to FIG. 17, the semiconductor device 1E may have a structure similar to that illustrated in FIG. 16. The same or similar elements in FIG. 17 as in FIG. 16 have been marked with similar reference numbers and duplicative descriptions have been omitted. The bottom layer 201 may be formed of a same material as illustrated in FIG. 16. A second conductive layers 303 may be disposed in the bottom layer 201 and contact the first barrier layer 401. The second conductive layers 303 may be referred to as a contact, a via, a conductive line, or a pad layer.

In some embodiments, the second conductive layers 303 may be formed of, for example, polycrystalline silicon, doped polycrystalline silicon, polycrystalline germanium, doped polycrystalline germanium, polycrystalline silicon germanium, doped polycrystalline silicon germanium, or a combination thereof. Specifically, the second conductive layers 303 is formed of polycrystalline silicon or doped polycrystalline silicon. The second conductive layers 303 including silicon atoms may react with the titanium film formed on the bottom layer 201 to form titanium silicide. Therefore, the bottom portion 401B of the first barrier layer 401 may be formed of titanium silicide and the two side portions 401S of the first barrier layer 401 may be formed of titanium nitride.

Alternatively, in some other embodiments, the second conductive layers 303 may be formed of, for example, copper, tungsten, aluminum, silver, titanium, tantalum, cobalt, zirconium, ruthenium, or combinations thereof. Due to the material of the second conductive layers 303, no silicon atoms can react with the titanium film to form titanium silicide. As a result, the titanium film formed on the bottom layer 201 may also react with ammonia to be turned into titanium nitride. Therefore, the bottom portion 401B and the two side portions 401S of the first barrier layer 401 may be all formed of titanium nitride.

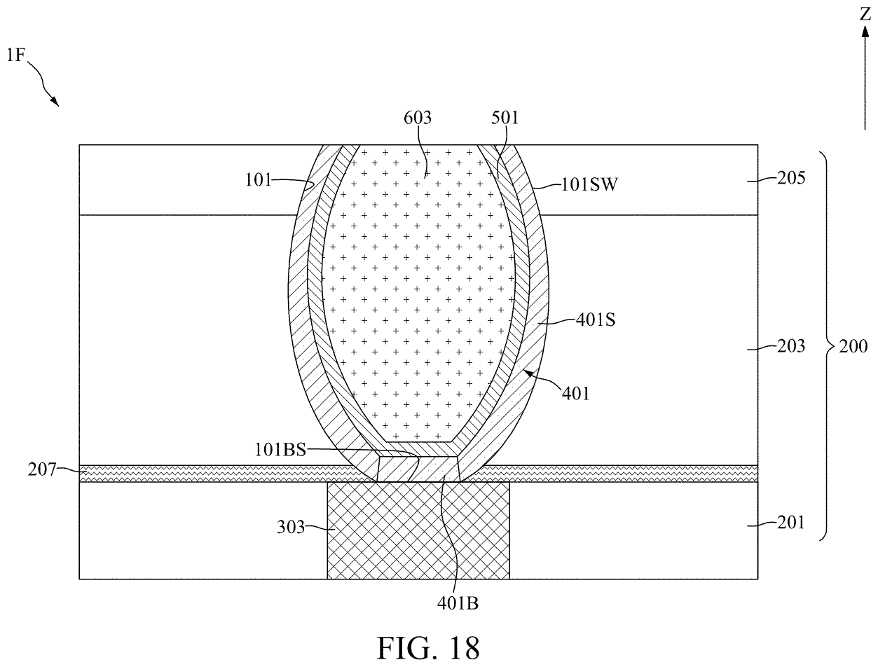

With reference to FIG. 18, the semiconductor device 1F may have a structure similar to that illustrated in FIG. 17. The same or similar elements in FIG. 18 as in FIG. 17 have been marked with similar reference numbers and duplicative descriptions have been omitted. The semiconductor device 1F may include an etch stop layer 207 disposed between the first dielectric layer 203 and the bottom layer 201. The etch stop layer 207 may be formed of, for example, silicon nitride, silicon carbon nitride, silicon oxycarbide, or a combination thereof.

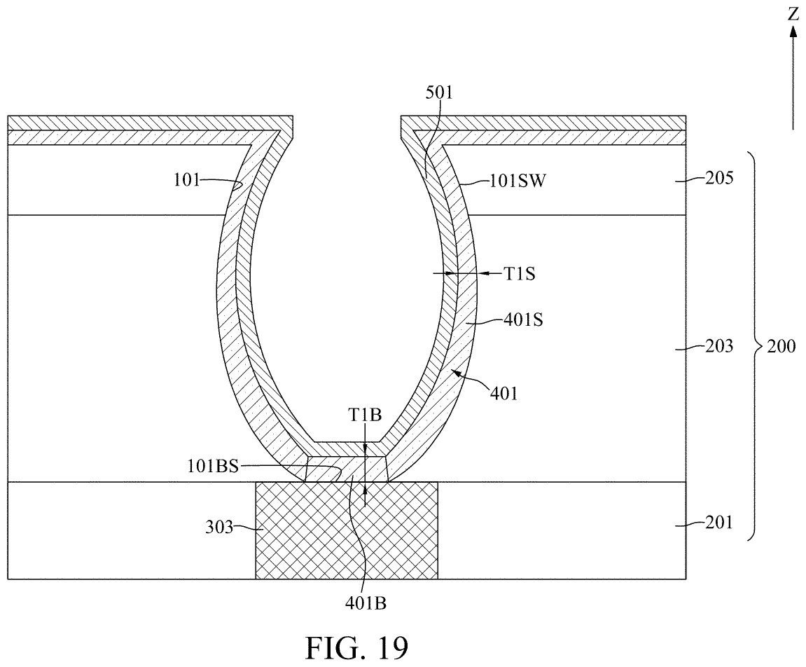

FIGS. 19 to 22 illustrate, in schematic cross-sectional view diagrams, a flow for fabricating a semiconductor device 1G in accordance with another embodiment of the present disclosure.

With reference to FIG. 19, the hole 101, the second conductive layers 303, and the target layer 200 including the bottom layer 201, the first dielectric layer 203, and the second dielectric layer 205 may be fabricated with a procedure similar to that illustrated in FIG. 17. The first barrier layer 401 may be conformally formed in the hole 101 and on the top surface of the second dielectric layer 205. The first barrier layer 401 may include the bottom portion 401B and the two side portions 401S. The thickness T1B of the bottom portion 401B may be greater than the thickness T1S of the two side portions 401S. The two side portions 401S may be formed of, for example, titanium nitride. The bottom portion 401B may be formed of, for example, titanium nitride or titanium silicide. The second barrier layer 501 may be conformally formed on the first barrier layer 401.

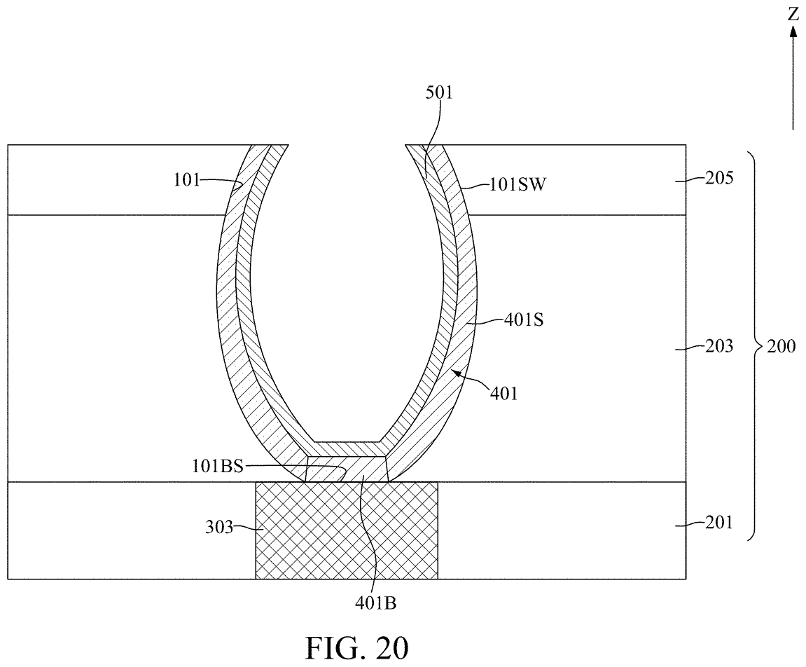

With reference to FIG. 20, the first barrier layer 401 and the second barrier layer 501 formed above the top surface of the second dielectric layer 205 may be removed. For example, a photoresist layer may be formed in the hole 101 to protect the first barrier layer 401 and the second barrier layer 501 in the hole and an etch back process may be performed to remove the first barrier layer 401 and the second barrier layer 501 on the top surface of the second dielectric layer 205.

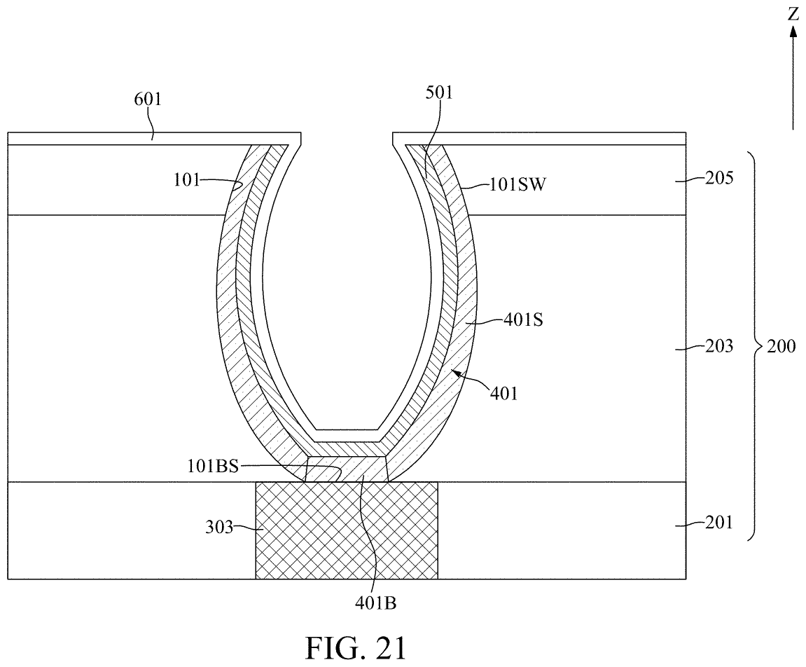

With reference to FIG. 21, a middle insulation layer 601 may be conformally formed in the hole 101 and on the top surface of the second dielectric layer 205. The middle insulation layer 601 may have a thickness between about 0.5 nm and about 5.0 nm. In some embodiments, the thickness of the middle insulation layer 601 may be between about 0.5 nm and about 2.5 nm. The middle insulation layer 601 may be formed of, for example, a high-k dielectric material such as metal oxide, metal nitride, metal silicate, transition metal-oxide, transition metal-nitride, transition metal-silicate, oxynitride of metal, metal aluminate, zirconium silicate, zirconium aluminate, or a combination thereof.

Specifically, the middle insulation layer 601 may be formed of hafnium oxide, hafnium silicon oxide, hafnium silicon oxynitride, hafnium tantalum oxide, hafnium titanium oxide, hafnium zirconium oxide, hafnium lanthanum oxide, lanthanum oxide, zirconium oxide, titanium oxide, tantalum oxide, yttrium oxide, strontium titanium oxide, barium titanium oxide, barium zirconium oxide, lanthanum silicon oxide, aluminum silicon oxide, aluminum oxide, silicon nitride, silicon oxynitride, silicon nitride oxide, or a combination thereof. In other embodiments, the middle insulation layer 601 may be a multi-layer structure that includes, for example, one layer of silicon oxide and another layer of high-k dielectric material, layers consisting of silicon oxide-silicon nitride-silicon oxide, or layers consisting of zirconium oxide-aluminum oxide-zirconium oxide.

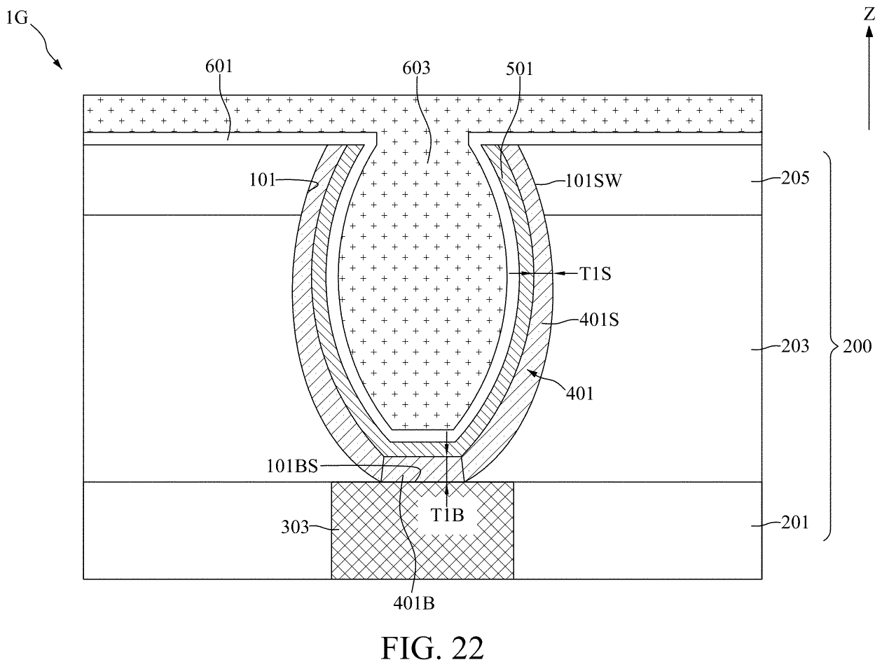

With reference to FIG. 22, a top conductive layer 603 may be formed on the middle insulation layer 601 and completely fill the hole 101. The top conductive layer 603 may be formed of, for example, copper, tungsten, aluminum, silver, titanium, tantalum, cobalt, zirconium, ruthenium, metal carbides, metal nitrides, transition metal aluminides, polycrystalline silicon, doped polycrystalline silicon, polycrystalline germanium, doped polycrystalline germanium, polycrystalline silicon germanium, doped polycrystalline silicon germanium, or a combination thereof. The top conductive layer 603, the middle insulation layer 601, the second barrier layer 501, and the first barrier layer 401 may together configure a capacitor structure. The first barrier layer 401 and the second barrier layer 501 may be referred to as a bottom electrode of the capacitor structure.

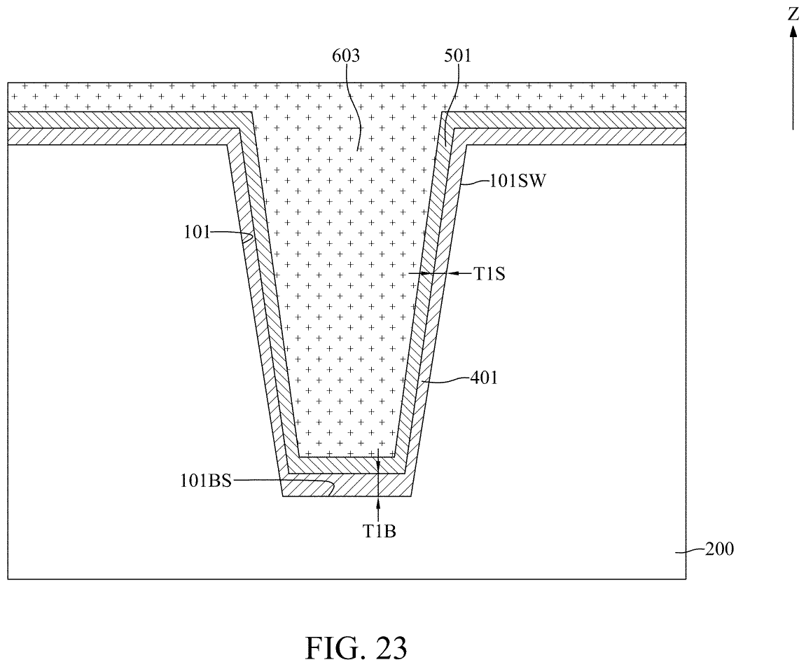

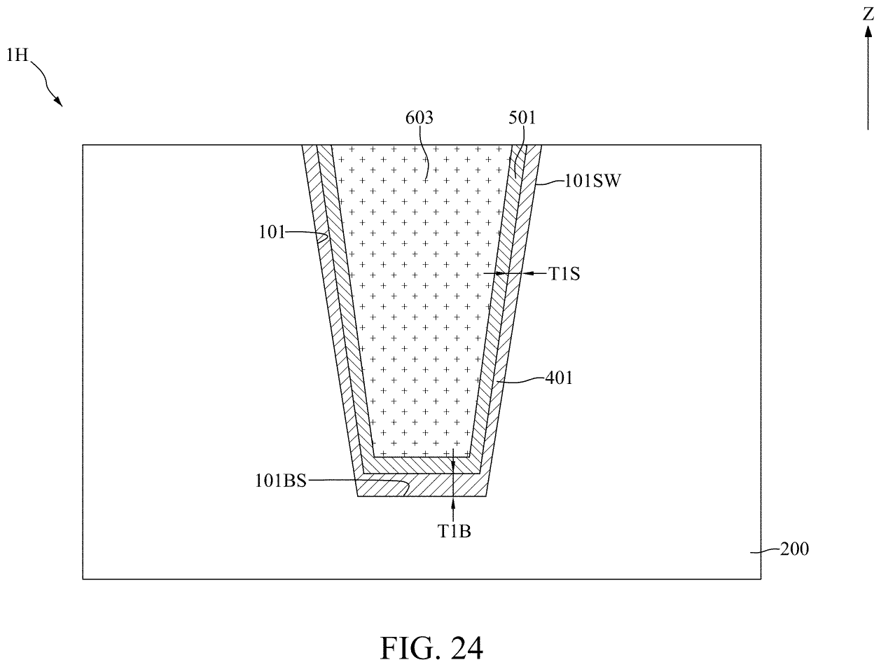

FIGS. 23 and 24 illustrate, in schematic cross-sectional view diagrams, a flow for fabricating a semiconductor device 1H in accordance with another embodiment of the present disclosure.

With reference to FIG. 23, the target layer 200 may be formed of a similar structure and may be formed of a similar material as illustrated in FIG. 2. The hole 101 may include a bottom surface 101BS and two sidewalls 101SW. The bottom surface 101BS may be horizontally disposed in a cross-sectional perspective. The two sidewalls 101SW may be connected to two ends of the bottom surface 101BS. The two sidewalls 101SW may have slanted cross-sectional profiles. The width of the sidewalls 101SW may gradually become wider from bottom to top along the direction Z. In other words, each of the two sidewalls 101SW may have a uniform slope.

The first barrier layer 401 may be conformally formed in the hole 101 and on the top surface of the second dielectric layer 205 with a procedure similar to that illustrated in FIGS. 3 and 4. The thickness T1B of the first barrier layer 401 formed on the bottom surface 101BS of the hole 101 may be greater than the thickness T1S of the first barrier layer 401 formed on the two sidewalls 101SW of the hole 101. The second barrier layer 501 and the top conductive layer 603 may be formed with a procedure similar to that illustrated in FIGS. 5 to 8.

With reference to FIG. 24, a planarization process, such as chemical mechanical polishing, may be performed until the top surface of the target layer 200 is exposed to remove excess material, provide a substantially flat surface for subsequent processing steps, and concurrently form the conductive feature configured from the first barrier layer 401, the second barrier layer 501, and the top conductive layer 603.

One aspect of the present disclosure provides a semiconductor device including a target layer, a hole inwardly positioned from a top surface of the target layer and including a bottom surface and two sidewalls adjoining to two ends of the bottom surface, a first barrier layer conformally positioned on the bottom surface of the hole and the two sidewalls of the hole, a second barrier layer conformally positioned on the first barrier layer, and a top conductive layer positioned on the second barrier layer. A thickness of the first barrier layer positioned on the bottom surface of the hole is greater than a thickness of the first barrier layer positioned on the two sidewalls of the hole. The second barrier has a substantially uniform thickness.

Another aspect of the present disclosure provides a semiconductor device including a target layer, a hole inwardly positioned from a top surface of the target layer and including a bottom surface and two sidewalls adjoining to two ends of the bottom surface, a first barrier layer including a bottom portion conformally positioned on the bottom surface of the hole and two side portions conformally positioned on the two sidewalls of the hole and connecting to two ends of the bottom portion, a second barrier layer conformally positioned on the first barrier layer, a middle insulation layer conformally positioned on the second barrier layer, and a top conductive layer positioned on the middle insulation layer. A thickness of the bottom portion of the first barrier layer is greater than thicknesses of the two sidewall portions of the first barrier layer. The second barrier has a substantially uniform thickness.

Another aspect of the present disclosure provides a method for fabricating a semiconductor device including providing a target layer, forming a hole in the target layer, conformally forming a first barrier layer in the hole, conformally forming a second barrier layer on the first barrier layer, and forming a top conductive layer (FIG. 8, 603) on the second barrier layer to fill the hole. The hole includes a bottom surface and two sidewalls adjoining to two ends of the bottom surface. A thickness of the first barrier layer formed on the bottom surface of the hole is greater than a thickness of the first barrier layer formed on the two sidewalls of the hole. The second barrier layer has a substantially uniform thickness.

Due to the design of the semiconductor device of the present disclosure, step coverage for the hole 101 may be improved. As a result, the following filling of the top conductive layer 603 may be proceeded without formation of void. Therefore, reliability of the semiconductor device 1A may be increased.

Although the present disclosure and its advantages have been described in detail, it should be understood that various changes, substitutions, and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a target layer;
a hole inwardly positioned from a top surface of the target layer and comprising a bottom surface and two sidewalls adjoining to two ends of the bottom surface;
a first barrier layer conformally positioned on the bottom surface of the hole and the two sidewalls of the hole;
a second barrier layer conformally positioned on the first barrier layer; and
a top conductive layer positioned on the second barrier layer;
wherein a thickness of the first barrier layer positioned on the bottom surface of the hole is greater than a thickness of the first barrier layer positioned on the two sidewalls of the hole;
wherein the second barrier has a substantially uniform thickness.

2. The semiconductor device of claim 1, wherein the two sidewalls of the hole are curved and faced to each other.

3. The semiconductor device of claim 1, wherein the two sidewalls have uniform slopes.

4. The semiconductor device of claim 2, wherein the target layer comprises a bottom layer, a first dielectric layer positioned on the bottom layer, and a second dielectric layer positioned on the first dielectric layer, the hole is positioned along the first dielectric layer and the second dielectric layer, and the bottom surface of the hole is substantially coplanar with a top surface of the bottom layer.

5. The semiconductor device of claim 2, wherein an aspect ratio of the hole is between about 1:1 and about 1:25.

6. The semiconductor device of claim 5, wherein the first barrier comprises titanium, titanium nitride, titanium silicide, or a combination thereof.

7. The semiconductor device of claim 5, wherein the second barrier layer comprises titanium nitride.

8. A semiconductor device, comprising:
a target layer;
a hole inwardly positioned from a top surface of the target layer and comprising a bottom surface and two sidewalls adjoining to two ends of the bottom surface;
a first barrier layer comprising a bottom portion conformally positioned on the bottom surface of the hole and two side portions conformally positioned on the two sidewalls of the hole and connecting to two ends of the bottom portion;
a second barrier layer conformally positioned on the first barrier layer;
a middle insulation layer conformally positioned on the second barrier layer;
and a top conductive layer positioned on the middle insulation layer;
wherein a thickness of the bottom portion of the first barrier layer is greater than thicknesses of the two sidewall portions of the first barrier layer;
wherein the second barrier has a substantially uniform thickness.

9. The semiconductor device of claim 8, wherein the two sidewalls of the hole are curved and faced to each other.

10. The semiconductor device of claim 8, wherein the target layer comprises a bottom layer, a first dielectric layer positioned on the bottom layer, and a second dielectric layer positioned on the first dielectric layer, the hole is positioned along the first dielectric layer and the second dielectric layer, and the bottom surface of the hole is substantially coplanar with a top surface of the bottom layer.

11. A method for fabricating a semiconductor device, comprising:
providing a target layer;
forming a hole in the target layer, wherein the hole comprises a bottom surface and two sidewalls adjoining to two ends of the bottom surface;
conformally forming a first barrier layer in the hole, wherein a thickness of the first barrier layer formed on the bottom surface of the hole is greater than a thickness of the first barrier layer formed on the two sidewalls of the hole;
conformally forming a second barrier layer on the first barrier layer, wherein the second barrier layer has a substantially uniform thickness; and
forming a top conductive layer on the second barrier layer to fill the hole.

12. The method for fabricating the semiconductor device of claim 11, wherein the first barrier layer is formed by using a source gas containing a precursor and a reductant through chemical vapor deposition.

13. The method for fabricating the semiconductor device of claim 12, wherein the precursor is titanium tetrachloride and the reductant is hydrogen gas.

14. The method for fabricating the semiconductor device of claim 11, wherein the step of conformally forming the first barrier layer comprises:
introducing a source gas containing a precursor onto the hole to form a continuous thin film on the hole; and
flowing a reactant to turn the continuous thin film into the first barrier layer.

15. The method for fabricating the semiconductor device of claim 14, wherein the precursor is titanium tetrachloride and the reactant is ammonia.

16. The method for fabricating the semiconductor device of claim 11, wherein the step of conformally forming the second barrier layer on the first barrier layer comprises:
introducing a source gas containing a precursor and a reactant onto the first barrier layer to form a continuous thin film on the first barrier layer; and
introducing the reactant to turn the continuous thin film into the second barrier layer.

17. The method for fabricating the semiconductor device of claim 16, wherein the precursor is tetrachloride and the reactant is ammonia.

18. The method for fabricating the semiconductor device of claim 11, wherein the step of conformally forming the second barrier layer on the first barrier layer comprises:
introducing a source gas containing a precursor onto the first barrier layer to form a monolayer on the first barrier layer; and
introducing a reactant to turn the monolayer into the second barrier layer.

19. The method for fabricating the semiconductor device of claim 18, wherein the precursor is tetrachloride and the reactant is ammonia.

20. The method for fabricating the semiconductor device of claim 11, wherein the first barrier comprises titanium, titanium nitride, titanium silicide, or a combination thereof.
